(19) United States
(12) Patent Application Publication
(10) Pub. No.: US 2026/0237442 A1
(43) Pub. Date: Aug. 13, 2026

(54) INFORMATION PROCESSING APPARATUS AND MEMORY SYSTEM

(71) Applicant: Kioxia Corporation, Tokyo (JP)

(72) Inventor: Yusuke KOMANO, Yokohama (JP)

(73) Assignee: Kioxia Corporation, Tokyo (JP)

(21) Appl. No.: 19/416,079

(22) Filed: Dec. 11, 2025

(30) Foreign Application Priority Data
Feb. 10, 2025 (JP) 2025-020106

(51) Int. Cl. G11C 16/26; G11C 16/04; G11C 16/30

(52) U.S. Cl. CPC G11C 16/26; G11C 16/0483; G11C 16/30

(57) ABSTRACT

An information processing apparatus has a first string including a first portion and a second portion connected in series, a second string including a third portion and a fourth portion connected in series, a first wiring line to which one end of the first string and one end of the second string are connected, a first switching controller that switches and controls currents flowing through the first portion and the third portion, a second switching controller that switches and controls a resistance value of the second portion, and a third switching controller that switches and controls a resistance value of the fourth portion.

### CROSS REFERENCE TO RELATED APPLICATIONS

This application is based upon and claims the benefit of priority from the prior Japanese Patent Application No. 2025-020106, filed on Feb. 10, 2025, the entire contents of which are incorporated herein by reference.

### FIELD

A first embodiment of the present invention relates to an information processing apparatus and a memory system.

### BACKGROUND

In machine learning, it is necessary to perform a large amount of multiply-accumulate operations at high speed, and thus, studies to perform multiply-accumulate operations by hardware are in progress. Specifically, a Computer In Memory (CIM) has attracted attention, in which a query and a key are multiplied by using a word line and memory cell of a semiconductor memory and a current corresponding to a result of the multiplication is applied to a bit line.

For example, in a case where, in a NAND flash memory, a query and a key are multiplied by a string in which a plurality of memory cell transistors is serially connected, a circuit for setting a voltage of each word line connected to a gate of each memory cell transistor may be complicated. The number of stacked layers for a NAND flash memory is on the rise, while the number of memory cell transistors included in strings also increases with the increase in the number of stacked layers. Therefore, a size of the circuit for setting a voltage of each word line described above also increases, and there is a possibility that a degree of integration of the NAND flash memory cannot be improved.

### BRIEF DESCRIPTION OF THE DRAWINGS

FIG. 1 is a circuit diagram illustrating a basic configuration of a CIM;

FIG. 2A is a table illustrating an example in which each of first data and second data takes on four values;

FIG. 2B is a table illustrating results of calculating an inner product of 4-bit data corresponding to the first data and 4-bit data corresponding to the second data;

FIG. 3 is a graph plotting relationships between overdrive voltages and inner product values;

FIG. 4 is a circuit diagram illustrating an example of a string;

FIG. 5 is an equivalent circuit diagram of the string in FIG. 4;

FIG. 6 is a graph illustrating curves representing relationships between the overdrive voltage and a drain-source current of a transistor;

FIG. 7 is a circuit diagram of a main part of an information processing apparatus according to a comparative example;

FIG. 8 is a table illustrating relationships between query values and voltages selected by a first selector and a second selector in FIG. 7;

FIG. 9 is a circuit diagram of a main part of an information processing apparatus according to a first embodiment;

FIG. 10 is a diagram illustrating a configuration of a first string and a second string;

FIG. 11 is a detailed circuit diagram of strings of the information processing apparatus according to the first embodiment;

FIG. 12 is a graph illustrating correspondence relationships between threshold voltages set to respective transistors of a resistance adjustment layer of each string and current flowing through a resistance adjustment layer;

FIG. 13 is a table illustrating voltages supplied to gates of respective transistors of resistance adjustment layer and key layer; and

FIG. 14 is a block diagram illustrating a schematic configuration of a memory system including an information processing apparatus according to a second embodiment.

### DETAILED DESCRIPTION

In general, according to the embodiment, an information processing apparatus has a first string, a second string, a first wiring line, a first switching controller, a second switching controller and a third switching controller. The first string including a first portion and a second portion connected in series. The second string including a third portion and a fourth portion connected in series. The first wiring line to which one end of the first string and one end of the second string are connected. The first switching controller that switches and controls currents flowing through the first portion and the third portion. The second switching controller that switches and controls a resistance value of the second portion. The third switching controller that switches and controls a resistance value of the fourth portion.

Hereinafter, embodiments of an information processing apparatus and a memory system will be described with reference to the drawings. Although main components of the information processing apparatus and the memory system will be mainly described below, the information processing apparatus and the memory system may have components and functions that are not illustrated or described. The following description does not exclude components and functions that are not illustrated or described.

An information processing apparatus according to a first embodiment is, for example, a CIM that performs a multiply-accumulate operation by using a memory cell array of a non-volatile memory such as a NAND flash memory. In a normal memory, any one of a plurality of word lines is selected, and data is written to or read from a plurality of memory cells connected to the word line. Meanwhile, in the CIM, a plurality of word lines is simultaneously selected and logical operations are performed on a bit line. Therefore, as compared with a case where, as with a normal memory, data stored in a plurality of memory cells is read a plurality of times and transferred to a central processing unit (CPU), and a logical operation is performed with the CPU, the CIM can perform the logical operation at an extremely high speed, and can be applied to various types of information processing that require performing a large number of multiply-accumulate operations.

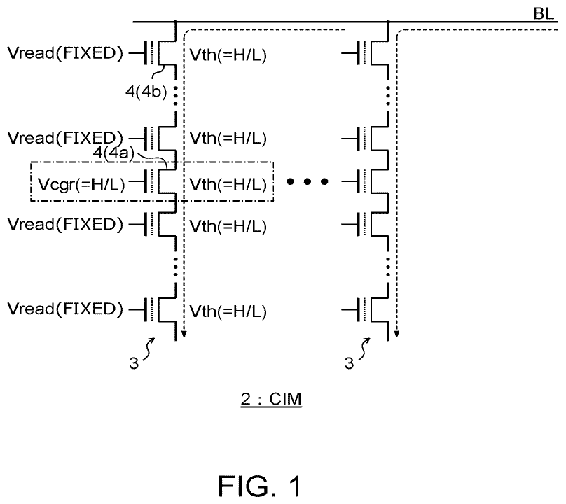

FIG. 1 is a circuit diagram illustrating a basic configuration of a CIM 2. The CIM 2 in FIG. 1 has a configuration similar to, for example, a NAND flash memory. More specifically, the CIM 2 in FIG. 1 includes a plurality of strings 3 connected to a bit line BL. Each string 3 includes a plurality of cascode-connected memory cell transistors 4. In the present specification, the “cascode-connected” may be referred to as “connected in series”. Hereinafter, the memory cell transistor 4 may be simply referred to as a transistor 4.

A threshold voltage corresponding to corresponding first data K is set to each transistor 4 that constitutes the strings 3. The first data K can take on, for example, two values of 0 or 1 for each transistor 4 that constitutes the strings 3. When the first data K is 1, the threshold voltage of a corresponding transistor 4 is lowered. When the first data K is 0, the threshold voltage of the corresponding transistor 4 is raised. Second data Q is input to a gate of each transistor 4 via a word line WL.

Any one of the plurality of transistors 4 (hereinafter, referred to as a transistor 4a, which is a specific transistor) in each string 3 is used for logical operation of the first data K and the second data Q, and transistors 4b, which are all the other transistors, are set to an on state. Specifically, by supplying a voltage whose voltage level is much higher than a threshold voltage of the transistor 4a (hereinafter, referred to as a Vread voltage) to a gate of each transistor 4b, the transistors 4b are set to the on state. Because the Vread voltage is much higher than a maximum threshold voltage that can be set to the transistors 4a and 4b, the transistors 4b each having a gate to which the Vread voltage is applied are turned on regardless of a threshold voltage of the transistors 4b.

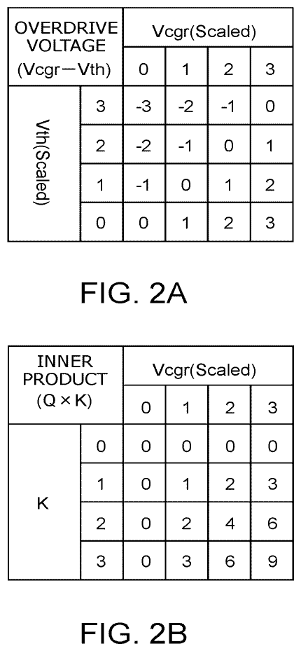

A multi-leveled threshold voltage exceeding the two values may be set to each transistor 4 in each string 3. By setting the multi-leveled threshold voltage to each transistor 4, comparison between multi-leveled first data K and second data Q can be performed in each string 3. FIG. 2A is a table illustrating an example in which each of first data K and second data Q takes on four values. Hereinafter, a voltage difference between the threshold voltage and gate voltage of the specific transistor 4a in the string 3 is referred to as an overdrive voltage. FIG. 2A illustrates a relationship among the first data K, the second data Q, and the overdrive voltage. In FIG. 2A, overdrive voltage is represented with a positive value if a gate voltage of the specific transistor 4a is higher than the threshold voltage, and with a negative value if the gate voltage is lower than the threshold voltage. As illustrated in FIG. 2A, the overdrive voltage may take on seven values, 3, 2, 1, 0, −1, −2, and −3.

FIG. 2B is a table illustrating results of calculating an inner product of four-valued data corresponding to the first data K and four-valued data corresponding to the second data Q. As illustrated in FIG. 2B, the inner product values may take on one of seven values, 9, 6, 4, 3, 2, 1, and 0. Each of the inner product values is a value proportional to current flowing through the string 3.

As can be seen from FIGS. 2A and 2B, the greater the overdrive voltage, the larger the inner product value. In addition, when the overdrive voltage has a negative value, the inner product value is zero, regardless of an absolute value thereof. This means that, when the overdrive voltage has a negative value, no current flows through the bit line and a potential of the bit line does not decrease. In addition, the overdrive voltage having the same value may take on different inner product values.

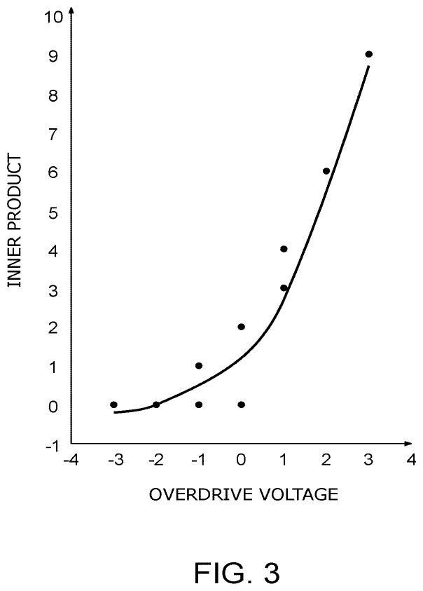

FIG. 3 is a graph plotting relationships between the overdrive voltages and the inner product values. As illustrated, when the overdrive voltage is 1, two inner product values other than zero may be taken on. Thus, it is not possible to generate a curve that passes through all plots with an inner product value other than zero. This means that the first data K and the second data Q cannot be identified from the inner product values.

As can be seen from the results in FIG. 3, in the CIM 2 having the configuration in FIG. 1 and FIG. 2B, there is a case where the first data K and the second data Q cannot be identified from current flowing through the bit line. In addition, because the threshold voltages and gate voltages of the transistors 4a and 4b that constitute the string 3 fluctuate due to manufacturing variations or the like, current flowing through the string 3 also fluctuates. The fluctuation in current flowing through the string 3 makes it more difficult to identify the first data K and the second data Q from the current.

As described above, in the string 3 having the configuration in FIG. 2, there is such a problem that first data K and second data Q cannot be identified from the current flowing through string 3. Meanwhile, in an information processing apparatus 10 according to the first embodiment described below, the first data K and the second data Q can be identified from the current flowing through the string 3.

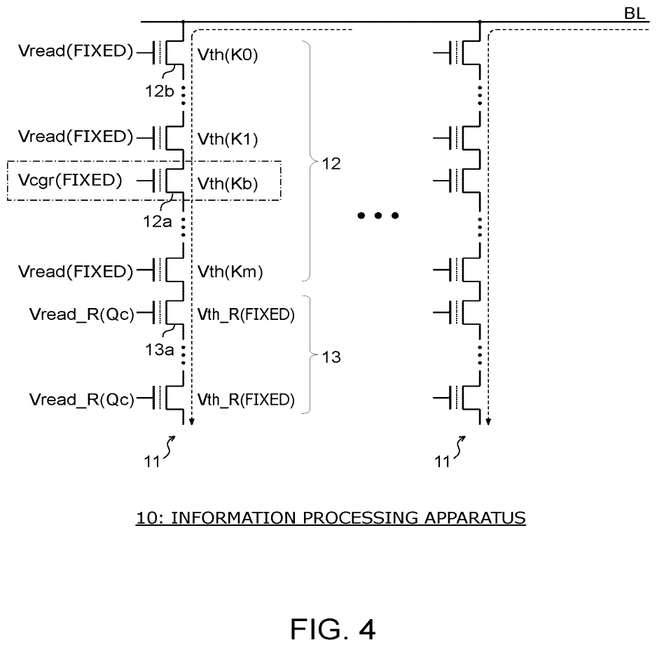

FIG. 4 is a circuit diagram illustrating an example of a string 11. In FIG. 4, a plurality of strings 11 is connected to one bit line (first wiring line) BL. The configuration of each string 11 in FIG. 4 is different from the configuration of each string 3 in FIG. 2. In each string 11 in FIG. 4, a current corresponding to a product of the first data K and the second data Q flows from the bit line BL. The first data K and the second data Q may be binary data or multi-leveled data with three or more values In the present specification, the first data K may be referred to as a key, and the second data Q may be referred to as a query.

The plurality of strings 11 is connected to one bit line BL, and, as described above, a current corresponding to the product of the first data K and the second data Q flows through each string 11. Therefore, a current obtained by adding currents flowing through the plurality of strings 11 flows through the bit line BL, and as the current flowing into each string 11 from the bit line BL increases, a potential of the bit line BL further decreases. Therefore, the first data K and the second data Q can be identified on the basis of the potential of the bit line BL.

The string 11 illustrated in FIG. 4 includes a plurality of cascode-connected memory cell transistors. Hereinafter, each of the memory cell transistors may be simply referred to as a transistor. The plurality of transistors that constitutes the string 11 is divided into a transistor group 12 and a transistor group 13. The transistor group 12 includes two or more transistors arranged on a side close to the bit line BL. The transistor group 13 includes one or more transistors arranged on a side farther from the bit line BL than the transistor group 12. In the present specification, the transistor group 12 may be referred to as a key layer 15, and the transistor group 13 may be referred to as a resistance adjustment layer 16 or a resistance layer.

A threshold voltage corresponding to corresponding first data K is set to transistors 12a and 12b in the transistor group 12. A voltage corresponding to corresponding second data Q is applied to a gate of each transistor 13a in the transistor group 13. The first data K is provided by the number of transistors 12a and 12b in the transistor group 12. The second data Q is provided by the number of transistors in the transistor group 13, for example.

Different word lines WL are connected to gates of the transistors 12a and 12b in the transistor group 12 that constitutes the string 11, and the gates of the respective transistors 13a in the transistor group 13 that constitutes the string 11. A first voltage Vcgr applied to a gate of any one transistor 12a in the transistor group 12 is supplied via a corresponding word line WL. Furthermore, the second data Q applied to the gate of each transistor 13a in the transistor group 13 is supplied via the corresponding word line WL.

The string 11 carries a current, the current corresponding to a product of the first data K corresponding to a threshold voltage of any one transistor 12a of the transistors 12a and 12b in the transistor group 12, and the second data Q applied to the gate of each transistor 13a in the transistor group 13.

More specifically, the transistor group 12 in the string 11 in FIG. 4 includes an m (m is an arbitrary integer of two or more) number of cascode-connected transistors 12a and 12b. A threshold voltage corresponding to corresponding first data K among the m number of first data K is set to each of the m transistors 12a and 12b.

The first voltage Vcgr is applied to the gate of any one transistor 12a among the m number of transistors 12a and 12b, and a second voltage Vread is applied to the gates of all the other transistors 12b.

A current corresponding to an overdrive voltage flows through the transistor group 12. The overdrive voltage is a voltage difference between the threshold voltage of the transistor 12a among the m number of transistors 12a and 12b, and the first voltage Vcgr. The transistor 12a has a gate to which the first voltage Vcgr is applied. Of the m number of transistors 12a and 12b, the transistor 12a having a gate to which the first voltage Vcgr is applied operates in a subthreshold region or a linear region, and the transistors 12b each having a gate to which the second voltage Vread is applied operate in a saturation region or the linear region.

The transistor group 13 includes one or more transistors 13a, and the one or more transistors 13a are set to the same threshold voltage, for example. Corresponding second data Q among the one or more second data Q is applied to the gate of each of the one or more transistors 13a. Each of the one or more transistors 13a has a resistance value corresponding to a voltage difference between corresponding second data Q and the threshold voltage. Note that the number of the second data Q and the number of the transistors 13a in the transistor group 13 do not necessarily have to coincide with each other. In addition, threshold voltages of the transistors 13a in the transistor group 13 are not necessarily the same.

The second data Q may be applied to the gate of each transistor 13a such that drain-source resistances of the transistors 13a in the transistor group 13 are the same. Alternatively, the second data Q may be applied to the gate of each transistor 13a such that the drain-source resistances of the transistors 13a in the transistor group 13 are different from each other.

Because the transistors 13a are cascode-connected in a case where there are two or more transistors 13a in the transistor group 13, source voltages of the transistors 13a are different from each other. Therefore, when a drain-source resistance value of each transistor 13a is set, it is necessary to take into account the source voltage of each transistor 13a. More specifically, in a case where the plurality of transistors 13a is cascode-connected in the transistor group 13, a transistor 13a closer to the transistor group 12 has a higher source voltage. Therefore, a voltage level of the second data Q applied to the gate voltage needs to be higher.

A current I flowing through the string 11 is expressed by the following Mathematical Formula (1).

$$I = a \times ( Kb \times Qc ) \qquad ( 1 )$$

In Mathematical Formula (1), a represents a proportional coefficient, Kb represents first data for setting a threshold voltage of the transistor 12a included in the transistor group 12 and having a gate to which the first voltage Vcgr is applied, and Qc represents second data applied to the gates of the transistors 13a in the transistor group 13.

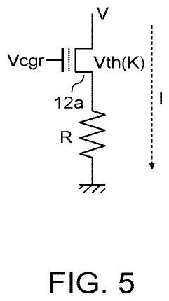

FIG. 5 is an equivalent circuit diagram of the string 11 in FIG. 4. In FIG. 5, the transistor group 12 is represented by one transistor 12a, and the transistor group 13 is represented by one resistance R. The transistor 12a in FIG. 5 is the transistor 12a among the plurality of transistors included in the transistor group 12 and having a gate to which the first voltage Vcgr is applied. Because all the other transistors 12b other than the transistor 12a included in the transistor group 12 and having a gate to which the first voltage Vcgr is applied are set to the on state, circuit operation of the other transistors 12b can be omitted.

The resistance R in FIG. 5 is a combined resistance value of source-drain resistances of one or more transistors 13a in the transistor group 13. Each transistor 13a in the transistor group 13 has a drain-source resistance corresponding to the voltage difference between the second data Q input to a corresponding gate and the threshold voltage. Therefore, the entire transistor group 13 has a resistance value obtained by adding the drain-source resistance values of the respective transistors 13a in the transistor group 13.

As described above, it is assumed that each string 11 in FIG. 4 operates, in the subthreshold region or the linear region, the transistor 12a included in the transistor group 12 and having a gate to which the first voltage Vcgr is applied, and operates, in the saturation region or the linear region, the transistors 12b each having a gate to which the second voltage Vread is applied. The subthreshold region is a region where the threshold voltage of the transistor is close to the gate voltage, and a drain-source current is small. The linear region is a region in which the drain-source current changes linearly with respect to the gate voltage.

Each string 11 in FIG. 4 changes a potential of the bit line BL by carrying a current corresponding to the product of the first data K and the second data Q. When the threshold voltage and gate voltage of each transistor that constitutes the string 11 fluctuate, the current flowing through the string 11 also fluctuates, and the potential of the bit line BL may also fluctuate. When the product of the first data K and the second data Q is calculated in each string 11, the current flowing through the string 11 is prevented from fluctuating as much as possible.

Assuming that the transistor in FIG. 5 operates in the subthreshold region, the current I between a drain and a source can be expressed by a transistor model equation illustrated in the following Mathematical Formula (2).

$$I = {I}_{o} 1 {0}^{\frac{{V}_{g s} - {V}_{t h}}{{S}_{g}} + \frac{{V}_{d s}}{{S}_{d}}} + ( 1 - {e}^{- \frac{{V}_{d s}}{{V}_{t h}}} ) \qquad ( 2 )$$

In Mathematical Formula (2), Vgs represents a gate-source voltage of the transistor, Vds represents a drain-source voltage of the transistor, and Vth represents a threshold voltage of the transistor. Sg represents a subthreshold swing parameter, and Sd represents a drain-induced barrier-lowering parameter. Io represents a proportional coefficient determined by a gate length L, a gate width, mobility, and the like of each transistor in the string.

When the second term on the right-hand side of Mathematical Formula (2) is ignored, logarithmic conversion is performed, and voltage drop at the resistance R in FIG. 5 due to the current I is taken into consideration, the following Mathematical Formula (3) is obtained.

$$In ( I ) + a \times I = b \times ( Vg - Vth ) + c \qquad ( 3 )$$

Vg in Mathematica Formula represents a gate potential of the transistor. In addition, a, b, and c in Mathematical Formula (3) are represented by Mathematical Formulas (4), (5), and (6), respectively. Rb in Mathematical Formula (4) represents the resistance R in FIG. 5. V in Mathematical Formula (6) represents a drain voltage of the transistor 12a in FIG. 5.

$$a = \frac{{R}_{b}}{{S}_{g}} \times ln 10 \qquad ( 4 )$$

$$b = \frac{ln 10}{{S}_{g}} \qquad ( 5 )$$

$$c = \frac{V \cdot ln 10}{{S}_{d}} + ln {I}_{o} \qquad ( 6 )$$

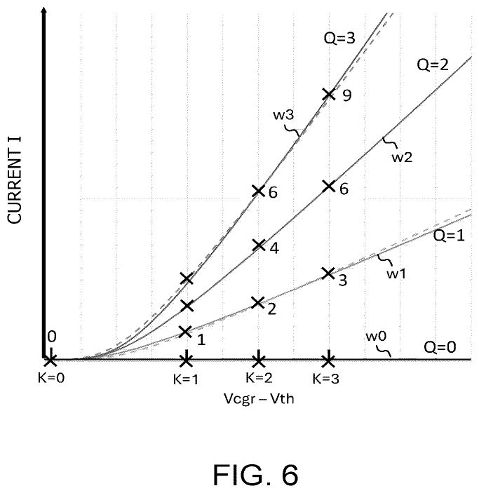

FIG. 6 is a graph illustrating curves representing relationships between the overdrive voltage and a drain-source current of the transistor 12a. In FIG. 6, the horizontal axis represents the overdrive voltage, and the vertical axis represents the drain-source current of the transistor 12a. Solid curves in FIG. 6 depict simulation waveforms calculated based on Mathematical Formula (3). Meanwhile, dashed curves depict waveforms each representing a case where fluctuation in the threshold voltage or gate voltage of each of the transistors 12a and 12b in the string 11 occurs.

FIG. 6 illustrates, where Q represents the second data Q applied to the gates of the transistors in the transistor group 13, a line w0 representing a case of Q=0, a curve w1 representing a case of Q=1, a curve w2 representing a case of Q=2, and a curve w3 representing a case of Q=3. When the second data Q changes, a resistance value of the transistor group 13 changes, and a curve representing a relationship between the overdrive voltage and the drain-source current of the transistor 12a is also different.

X points in FIG. 6 represent plot positions, each representing a drain-source current of the transistor 12a to which specific overdrive voltages are applied. When the threshold voltage and gate voltage of each of the transistors 12a, 12b, and 13a that constitute the string 11 fluctuate, the current flowing through the string 11 fluctuates, and the waveform shapes of the curves w1 to w3 in FIG. 6 also change. In order to correctly detect a result of the multiply-accumulate operation by monitoring the potential of the bit line BL even when the waveform shapes of the curves w1 to w3 change, it is desirable to provide the plot positions of the overdrive voltages in a region where any waveform shape among the waveform shapes of the curves w1 to w3 close to linear is present.

In the example in FIG. 6, the plot positions of all the overdrive voltages are provided in the linear region of the waveform shapes of the curves w1 to w3. Therefore, intervals between the plot positions are substantially equal, and an overdrive voltage can be identified without errors from the current flowing through the string 11. This means that the first data K and the second data Q can be identified from the current flowing through the string 11.

The waveform shapes of the curves w1 to w3 in FIG. 6 can be changed by adjusting the resistance value of the transistor group 13 in the string 11. In order to adjust the resistance value of the transistor group 13, for example, it is only required to adjust the threshold voltage of each transistor 13a in the transistor group 13. As described above, the threshold voltages of the transistors 13a in the transistor group 13 are the same. Therefore, by collectively changing the threshold voltages of the respective transistors 13a, the waveform shapes of the curves w1 to w3 can be similarly adjusted, and adjustment to widen a linear region of each curve can be performed.

Voltage levels of the overdrive voltages can be changed by adjusting a voltage level of the first voltage Vcgr applied to the gate of each transistor 12a in the transistor group 12. Therefore, the first voltage Vcgr can be adjusted such that the plot positions of the overdrive voltages are within a linear region of each of the curves w1 to w3.

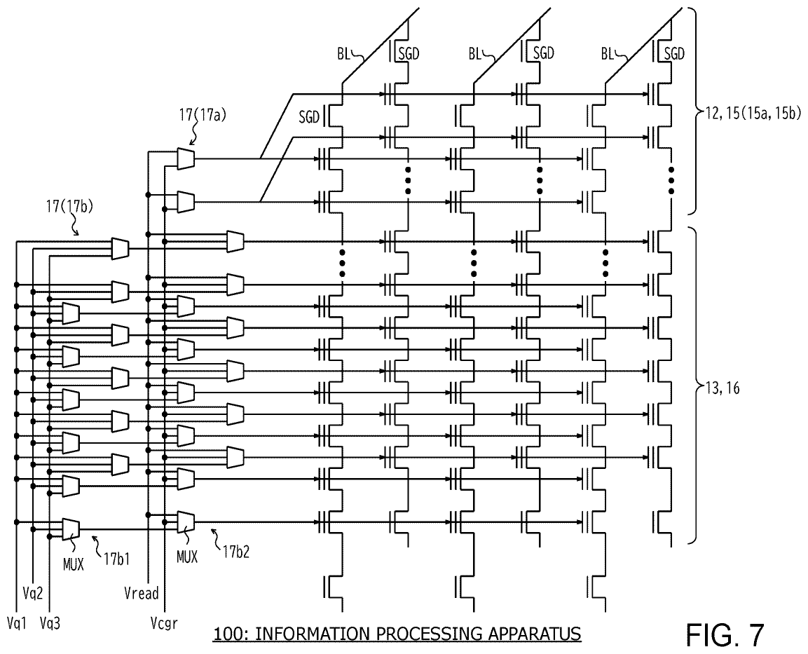

FIG. 7 is a circuit diagram of a main part of an information processing apparatus 100 according to a comparative example. FIG. 7 illustrates a circuit configuration in a case where a query and a key take on four values. In FIG. 4 described above, the voltage Vread or Vcgr is supplied to the gate of each transistor of the key layer 15 including the transistor group 12, and the voltage Vread or a voltage Vread_R corresponding to the query is supplied to the gate of each transistor of the resistance adjustment layer 16 including the transistor group 13. In practice, it is necessary to provide a gate selector that generates the voltage Vread_R.

The information processing apparatus 100 according to a comparative example illustrated in FIG. 7 includes a plurality of bit lines BL, a plurality of strings 11 connected to the respective bit lines BL, and gate selectors 17 that select a voltage to be supplied to a gate of each transistor included in each string 11.

As illustrated in FIG. 4, each string 11 includes a transistor group 12 that constitutes the key layer 15 and a transistor group 13 that constitutes a resistance adjustment layer 16. A preset fixed threshold voltage is set to each transistor that constitutes the transistor group 12 and each transistor that constitutes the transistor group 13. More specifically, the key layer 15 of each string 11 includes a selected key layer 15a and a non-selected key layer 15b. The selected key layer 15a includes one or more transistors, and the non-selected key layer 15b includes one or more transistors. Each transistor of the selected key layer 15a and each transistor of the non-selected key layer 15b are connected in series in the string 11.

A gate selector 17 selects a voltage to be supplied to the gate of each transistor that constitutes the transistor groups 12 and 13. The gate selector 17 includes a first selector 17a and a second selector 17b.

The first selector 17a selects a voltage to be supplied to each transistor of the transistor group 12 that constitutes the key layer 15 of each string 11. The first selector 17a supplies the voltage Vread or Vcgr to the gate of each transistor.

The first selector 17a includes one multiplexer (MUX) for each transistor of the selected key layer 15a and one multiplexer (MUX) for each transistor of the non-selected key layer 15b.

The second selector 17b selects a voltage to be supplied to each transistor of the transistor group 13 that constitutes the resistance adjustment layer 16 of each string 11. The second selector 17b includes a query selector 17b1 and a gate voltage selector 17b2.

The query selector 17b1 selects and outputs one of a plurality of voltages Vq1, Vq2, and Vq3 corresponding to a type of the query. FIG. 7 illustrates a circuit configuration in a case where the query and the key take on four values, but one of the four values of the query (for example, a minimum value Vq0 of the query) is not a target of selection by the query selector 17b1. When the query takes on the minimum value Vq0, no current flows through the string 11. Therefore, an SGD transistor, which is for control and provided in the string 11, is turned off so that no current flows through the string 11.

The query selector 17b1 includes one multi-selector (MUX) for each transistor of the transistor group 13 that constitutes the resistance adjustment layer 16 of each string 11. Each multiplexer selects one of the voltages Vq1, Vq2, and Vq3 and supplies the selected voltage to the gate of a corresponding transistor.

The gate voltage selector 17b2 selects and outputs any one of the voltage selected by the query selector 17b1, the voltage Vread, or the voltage Vcgr. The gate voltage selector 17b2 includes one multi-selector (MUX) for each transistor of the transistor group 13 that constitutes the resistance adjustment layer 16 of each string 11. Each multiplexer selects any one of the voltage selected by the query selector 17b1, the voltage Vread, or the voltage Vcgr, and supplies the selected voltage to the gate of the corresponding transistor.

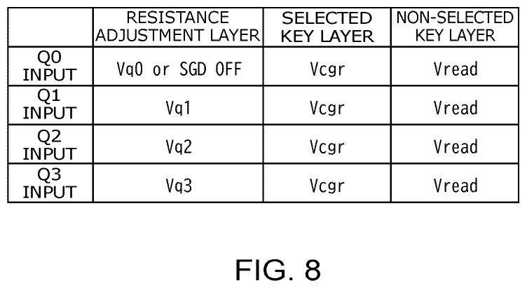

FIG. 8 is a table illustrating relationships between query values and voltages selected by the first selector 17a and the second selector 17b in FIG. 7. FIG. 8 illustrates an example in which the query takes on four values (Q0, Q1, Q2, and Q3).

As illustrated in FIG. 8, when the query is Q0, the SGD transistor of each string 11 is turned off. Therefore, an output voltage of the second selector 17b is not limited. Alternatively, when the query is Q0, the second selector 17b may select and output Vq0. In this case, it is not necessary to turn off the SGD transistor. The first selector 17a supplies the voltage Vcgr to the gate of each transistor of the selected key layer 15a and supplies the voltage Vread to the gate of each transistor of the non-selected key layer 15b.

When the query is Q1, the second selector 17b selects the voltage Vq1 and supplies Vq1 to the gate of each transistor of the resistance adjustment layer 16 of each string 11. The first selector 17a supplies the voltage Vcgr to the gate of each transistor of the selected key layer 15a of each string 11 and supplies the voltage Vread to the gate of each transistor of the non-selected key layer 15b.

When the query is Q2, the second selector 17b selects the voltage Vq2 and supplies Vq2 to the gate of each transistor of the resistance adjustment layer 16 of each string 11. The first selector 17a supplies the voltage Vcgr to the gate of each transistor of the selected key layer 15a of each string 11 and supplies the voltage Vread to the gate of each transistor of the non-selected key layer 15b.

When the query is Q3, the second selector 17b selects the voltage Vq3 and supplies Vq3 to the gate of each transistor of the resistance adjustment layer 16 of each string 11. The first selector 17a supplies the voltage Vcgr to the gate of each transistor of the selected key layer 15a of each string 11 and supplies the voltage Vread to the gate of each transistor of the non-selected key layer 15b.

As illustrated in FIGS. 7 and 8, in the information processing apparatus 100 according to a comparative example, a circuit scale of the second selector 17b increases as the number of types of queries increases.

### First Embodiment

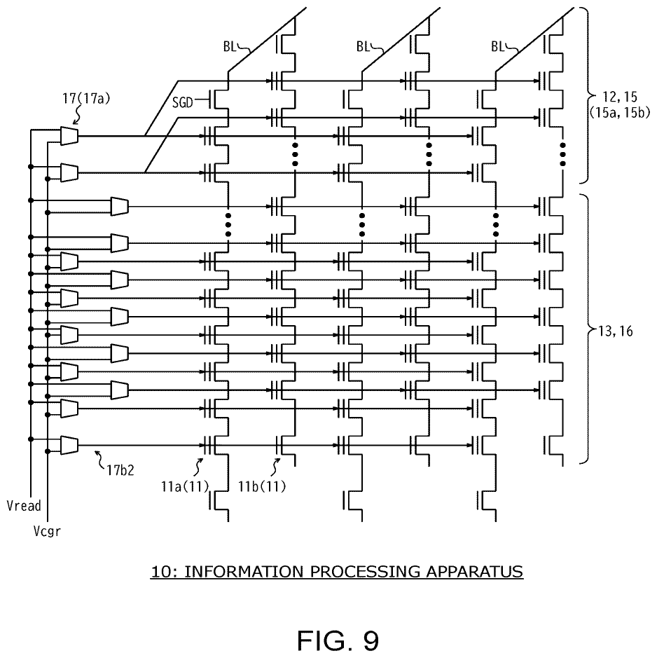

FIG. 9 is a circuit diagram of a main part of the information processing apparatus 10 according to the first embodiment. The information processing apparatus 10 according to the first embodiment includes a plurality of bit lines BL (first wiring lines), a plurality of strings 11 connected to the respective bit lines BL (first wiring lines), and gate selectors 17 that select a voltage to be supplied to a gate of each transistor included in each string 11.

The number of the plurality of strings 11 connected to one bit line BL (first wiring line) is not limited. Hereinafter, however, two strings 11 connected to one bit line BL (first wiring line) are referred to as a first string 11a and a second string 11b, for convenience.

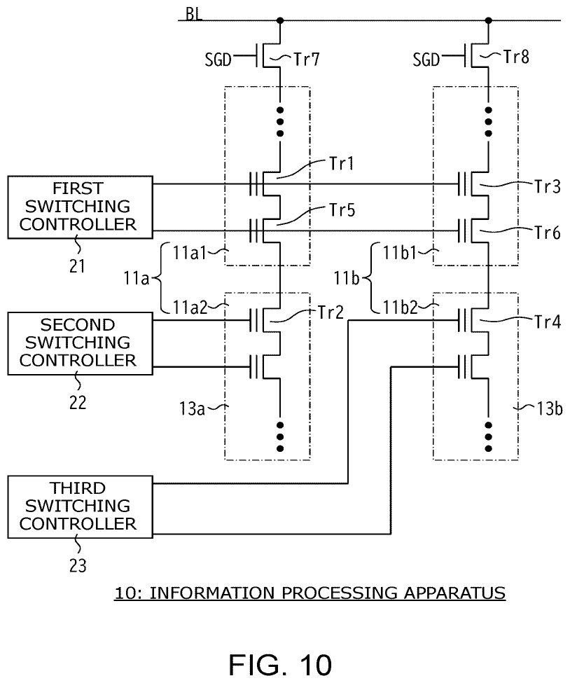

FIG. 10 is a diagram illustrating a configuration of the first string 11a and the second string 11b. The first string 11a includes a first portion 11a1 and a second portion 11a2 connected in series. The first portion 11a1 includes a first transistor Tr1 to which a threshold voltage corresponding to first data is set. The second portion 11a2 includes a second transistor Tr2 that is connected in series to the first transistor Tr1 and to which a threshold voltage corresponding to second data is set. In the present specification, the first data may be referred to as a key, and the second data may be referred to as a query. The first data and the second data may be binary data or multi-leveled data.

The second string 11b includes a third portion 11b1 and a fourth portion 11b2 connected in series. The third portion 11b1 includes a third transistor Tr3 to which a threshold voltage corresponding to third data is set. The fourth portion 11b2 includes a fourth transistor Tr4 that is connected in series to the third transistor Tr3 and to which a threshold voltage corresponding to fourth data is set. In the present specification, the third data may be referred to as a key, and the fourth data may be referred to as a query. The third data and the fourth data may be binary data or multi-leveled data.

Each of the first to fourth portions 11a1 to 11b2 includes at least one transistor. Typically, each of the first to fourth portions 11a1 to 11b2 includes two or more transistors. Hereinafter, an example in which each of the first to fourth portions 11a1 to 11b2 includes two or more transistors will be mainly described.

As illustrated in FIG. 6, each transistor included in each of the first to fourth portions 11a1 to 11b2 carries a current corresponding to a difference between the threshold voltage and the gate voltage.

The second portion 11a2 of the first string 11a includes a first transistor group 13a in which two or more second transistors Tr2 of a number corresponding to types of the second data are connected in series. The fourth portion 11b2 of the second string 11b includes a second transistor group 13b in which two or more fourth transistors Tr4 of a number corresponding to types of the fourth data are connected in series. A threshold voltage corresponding to the types of the second data is set to each of the two or more second transistors Tr2 included in the first transistor group 13a. A threshold voltage corresponding to the types of the fourth data is set to each of the two or more fourth transistors Tr4 included in the second transistor group 13b.

As described above, the first transistor group 13a of the second portion 11a2 of the first string 11a includes a plurality of second transistors Tr2 to which a threshold voltage for each type of the second data is set. The second transistor group 13b of the second portion 11a2 of the second string 11b includes a plurality of fourth transistors Tr4 to which a threshold voltage for each type of the fourth data is set.

The first portion 11a1 includes a fifth transistor Tr5 having a gate to which the second voltage having a higher voltage level than the first voltage supplied to a gate of the first transistor Tr1 is supplied. The fifth transistor Tr5 is connected in series to the first transistor Tr1. The third portion 11b1 includes a sixth transistor Tr6 having a gate to which the second voltage having a higher voltage level than the first voltage supplied to a gate of the third transistor Tr3 is supplied. The sixth transistor Tr6 is connected in series to the third transistor Tr3.

The first string 11a carries a first current corresponding to a product of the first data set or input to the first portion 11a1 and the second data set or input to the second portion 11a2. The second string 11b carries a second current corresponding to a product of the third data set for or input to the third portion 11b1 and the fourth data set or input to the fourth portion 11b2. The bit line BL (first wiring line) carries a third current obtained by adding the first current and the second current.

As described above, the first string 11a performs an inner product operation of a first vector corresponding to the first data and a second vector corresponding to the second data, and carries a current corresponding to an inner product value. Furthermore, the second string 11b performs the inner product operation of a third vector corresponding to the third data and a fourth vector corresponding to the fourth data, and carries a current corresponding to an inner product value.

A product of the first data and the second data calculated in the first string 11a and a product of the third data and the fourth data calculated by the second string 11b have characteristics similar to those in FIG. 6. That is, the first currents corresponding to the products of all combinations of types of the first data and types of the second data have different current values. The second currents corresponding to the products of all combinations of types of the third data and types of the fourth data have different current values. Therefore, the first to fourth data can be identified by sensing the current flowing through the bit lines BL (first wiring lines).

A gate selector 17 includes a first switching controller 21, a second switching controller 22, and a third switching controller 23. The first switching controller 21 switches and controls current flowing through the first portion 11a1 and the third portion 11b1. The second switching controller 22 switches and controls a resistance value of the second portion 11a2. The third switching controller 23 switches and controls a resistance value of the fourth portion 11b2.

The first switching controller 21 switches and controls the current flowing through the first portion 11a1 and the third portion 11b1 by supplying common voltages Vcgr and Vread to the first portion 11a1 and the third portion 11b1. The second switching controller 22 switches and controls the resistance value of the second portion 11a2 by supplying the voltage Vcgr or Vread corresponding to the second data to the second portion 11a2. The third switching controller 23 switches and controls the resistance value of the second portion 11a2 by supplying the voltage Vcgr or Vread corresponding to the fourth data to the fourth portion 11b2.

The first switching controller 21 supplies the gates of the first transistor Tr1 and third transistor Tr3 with voltages Vcgr and Vread at voltage levels corresponding to the threshold voltage of the first transistor Tr1 and the threshold voltage of the third transistor Tr3. For example, the first switching controller 21 supplies the voltage Vcgr to the gate of the first transistor Tr1 and supplies the voltage Vread to the gate of the third transistor Tr3.

The second switching controller 22 supplies the gate of the second transistor Tr2 with the voltage Vcgr or Vread at a voltage level corresponding to the threshold voltage of the second transistor Tr2. The third switching controller 23 supplies the gate of the fourth transistor Tr4 with a voltage having a voltage level corresponding to the threshold voltage of the fourth transistor Tr4.

The second switching controller 22 supplies the first voltage Vcgr to the gate of the specific second transistor Tr2 among the two or more second transistors Tr2 included in the first transistor group 13a, and supplies the second voltage Vread having a voltage level higher than the first voltage to the gates of the second transistors Tr2 other than the specific second transistor Tr2. The third switching controller 23 supplies the first voltage Vcgr to the gate of the specific fourth transistor Tr4 among the two or more fourth transistors Tr4 included in the second transistor group 13b, and supplies the second voltage Vread to the gates of the fourth transistors Tr4 other than the specific fourth transistor Tr4.

In the first transistor group 13a, a current corresponding to the threshold voltage flows between a drain and source of the specific second transistor Tr2. The second transistors Tr2 other than the specific second transistor Tr2 are turned on. Similarly, in the second transistor group 13b, a current corresponding to the threshold voltage flows between a drain and source of the specific fourth transistor Tr4. The fourth transistor Tr4 other than the specific fourth transistor Tr4 is turned on.

The specific second transistor Tr2 in the first transistor group 13a operates in the subthreshold region or the linear region, and the second transistors Tr2 other than the specific second transistor Tr2 operate in the saturation region or the linear region. The specific fourth transistor Tr4 in the second transistor group 13b operates in the subthreshold region or the linear region, and the fourth transistors Tr4 other than the specific fourth transistor Tr4 operate in the saturation region or the linear region.

The first transistor group 13a may be configured in which two or more second transistors Tr2 connected in series and to which the same threshold voltage is set are treated as a first set, and a plurality of first sets to which different threshold voltages are set is connected in series. The second transistor group 13b may be configured in which two or more fourth transistors Tr4 connected in series and to which the same threshold voltage is set are treated as a second set, and a plurality of second sets to which different threshold voltages are set is connected in series. The second switching controller 22 supplies the first voltage Vcgr to the gates of two or more second transistors Tr2 of any one of the first sets, and supplies the second voltage Vread to the gates of the second transistors Tr2 of the other first sets. The third switching controller 23 supplies the first voltage Vcgr to the gates of two or more fourth transistors Tr4 of any one of the second sets, and supplies the second voltage Vread to the gates of the fourth transistors Tr4 of the other second sets.

As described above, the reason why two or more second transistors Tr2 to which the same threshold voltage is set are provided in the first transistor group 13a is to average out variations in electrical characteristics of the individual second transistors Tr2.

Via a word line (second wiring line), the first switching controller 21 supplies the first voltage Vcgr and the second voltage Vread to the gate of the first transistor Tr1 of the first portion 11a1 and the gate of the third transistor Tr3 of the third portion 11b1.

Via a word line (third wiring line), the second switching controller 22 supplies the first voltage Vcgr or the second voltage Vread to the gate of the second transistor Tr2 of the second portion 11a2.

Via a word line (fourth wiring line), the third switching controller 23 supplies the first voltage Vcgr or the second voltage Vread to the gate of the fourth transistor Tr4 of the fourth portion 11b2.

As illustrated in FIG. 9, a plurality of strings 11 including the first string 11a and the second string 11b is connected to one bit line BL (first wiring line). The sum of the currents flowing through these strings 11 flows through the bit line BL (first wiring line).

As illustrated in FIG. 9, a plurality of strings 11 is connected to the second wiring line, the word line (third wiring line), and the word line (fourth wiring line). One end of each of the plurality of strings 11 connected to the second wiring line, the word line (third wiring line), and the word line (fourth wiring line) is connected to different bit lines BL (first wiring line).

In the present specification, a predetermined number of strings 11 to which the second wiring line, the word line (third wiring line), and the word line (fourth wiring line) are connected is referred to as a block. Each of the predetermined number of strings 11 included in one block is connected to a separate bit line BL (first wiring line).

The first portion 11a1 of the first string 11a includes a selected key layer 15a and a non-selected key layer 15b. The selected key layer 15a includes one or more first transistors Tr1. The non-selected key layer 15b includes one or more fifth transistors Tr5. The first switching controller 21 supplies the first voltage Vcgr to the gate of the first transistor Tr1 of the selected key layer 15a, and supplies the second voltage Vread to the gate of the fifth transistor Tr5 of the non-selected key layer 15b.

The third portion 11b1 of the second string 11b includes the selected key layer 15a and the non-selected key layer 15b. The selected key layer 15a includes one or more third transistors Tr3. The non-selected key layer 15b includes one or more sixth transistors Tr6. The first switching controller 21 supplies the first voltage Vcgr to the gate of the third transistor Tr3 of the selected key layer 15a, and supplies the second voltage Vread to the gate of the sixth transistor Tr6 of the non-selected key layer 15b.

As illustrated in FIG. 10, via a word line (fifth wiring line), the first switching controller 21 supplies the second voltage Vread to the gate of the fifth transistor Tr5 of the first portion 11a1 and the gate of the sixth transistor Tr6 of the third portion 11b1.

The first string 11a includes a seventh transistor Tr7 that switches whether or not to interrupt a current path of the first string 11a. The second string 11b includes an eighth transistor Tr8 that switches whether or not to interrupt a current path of the second string 11b. In the present specification, the seventh transistor Tr7 and the eighth transistor Tr8 may be collectively referred to as an SGD transistor.

The seventh transistor Tr7 is turned off when the second data has a predetermined value, and interrupts the current path of the first string 11a. The eighth transistor Tr8 is turned off when the fourth data has a predetermined value, and interrupts the current path of the first string 11a. The predetermined value is a minimum value of values that the second data or the fourth data is able to take on.

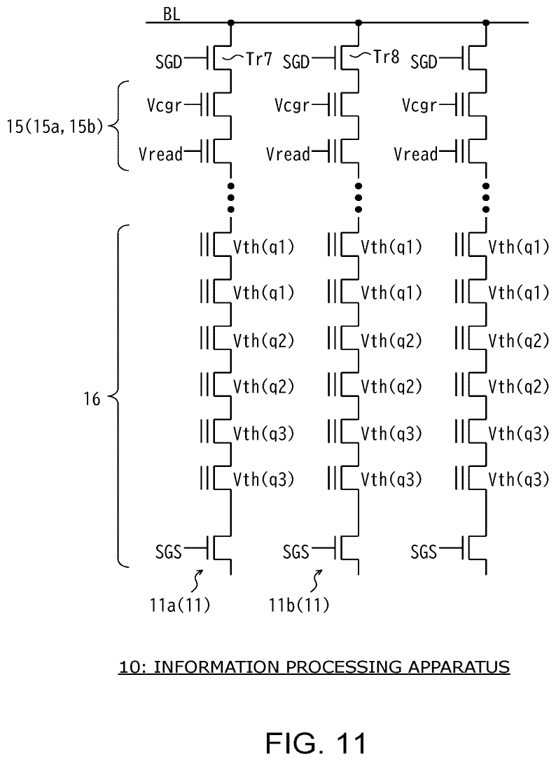

FIG. 11 is a detailed circuit diagram of the strings 11 of the information processing apparatus 10 according to the first embodiment. As illustrated in FIG. 11, each of the plurality of strings 11 including the first string 11a and second string 11b connected to the same bit line BL (first wiring line) is configured by directly connecting the SGD transistor, the key layer 15, the resistance adjustment layer 16, and an SGS transistor.

The SGD transistor and the SGS transistor are set to the on state when the strings 11 are used for the inner product operation. The SGD transistor corresponds to the seventh transistor Tr7 or the eighth transistor Tr8 described above. When a minimum value Q0 of the query is set in a string 11, the SGD transistor is turned off.

The key layer 15 of the string 11 is the first portion 11a1 or third portion 11b1 described above. As described above, the key layer 15 includes the selected key layer 15a and the non-selected key layer 15b. The selected key layer 15a includes one or more transistors (first transistor Tr1 or third transistor Tr3) connected in series. The non-selected key layer 15b includes one or more transistors (fifth transistor Tr5 or sixth transistor Tr6) connected in series.

The first voltage Vcgr is supplied to the gate of each transistor of the selected key layer 15a via the word line (second wiring line). The second voltage Vread is supplied to the gate of each transistor of the non-selected key layer 15b via the word line (fifth wiring line).

The resistance adjustment layer 16 of the string 11 is the second portion 11a2 or fourth portion 11b2 described above. The resistance adjustment layer 16 includes one or more transistors (second transistor Tr2 or fourth transistor Tr4) connected in series. FIG. 11 illustrates an example in which the resistance adjustment layer 16 includes two or more transistors.

A threshold voltage corresponding to a type of the query is set to each transistor of the resistance adjustment layer 16. For example, in a case of four-valued queries Q0 to Q3, three transistors to which threshold voltages of different queries are set are provided. As described above, when the query Q0 is selected, no current flows through the string 11, and thus the SGD transistor is turned off without providing the transistor to which the threshold voltage for the query Q0 is set. As a result, the number of transistors of the resistance adjustment layer 16 can be reduced.

As illustrated in FIG. 11, two or more transistors to which the same threshold voltage is set may be provided. By providing two or more transistors to which the same threshold voltage is set, as described above, variations in electrical characteristics of individual transistors can be averaged.

Threshold voltages corresponding to different queries can be set to the respective transistors of the resistance adjustment layer 16 of each of the plurality of strings 11 including the first string 11a and the second string 11b connected to the same bit line BL (first wiring line).

Similarly, threshold voltages corresponding to different keys can be set to the respective transistors of the selected key layer 15a of each of the plurality of strings 11 including the first string 11a and the second string 11b connected to the same bit line BL (first wiring line).

In the resistance adjustment layer 16 and the key layer 15, the first voltage Vcgr is supplied to the gate of a transistor to which a valid threshold voltage is set, and the second voltage Vread is supplied to the gate of a transistor to which the valid threshold voltage is not set. The transistor for which the second voltage Vread is supplied is turned on.

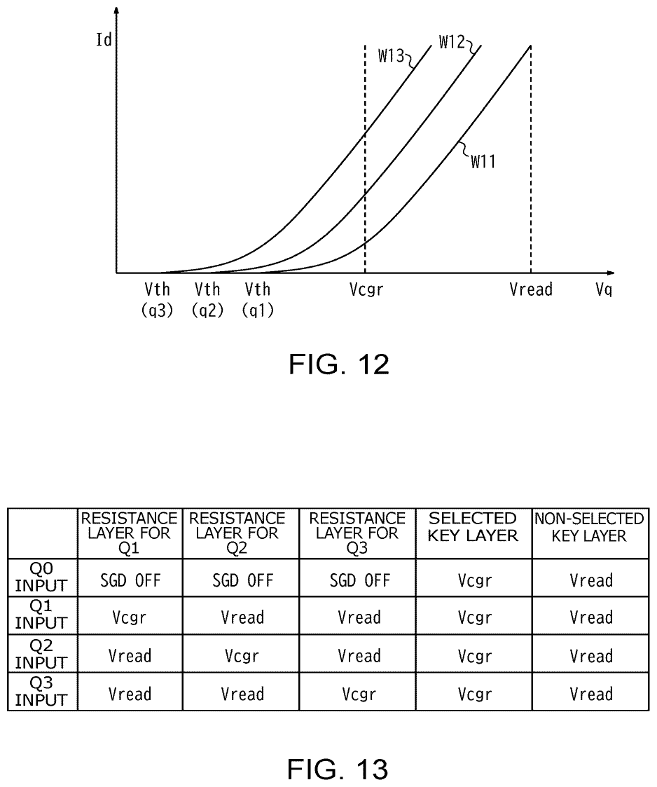

FIG. 12 is a graph illustrating correspondence relationships between threshold voltages set to respective transistors of the resistance adjustment layer 16 of each string 11 and current flowing through the resistance adjustment layer 16. FIG. 12 illustrates curves W11 to W13 of the correspondence relationship among three transistors to which threshold voltages corresponding to different queries q1 to q3 are set.

As illustrated in FIG. 12, the first voltage Vcgr supplied to the gate of a transistor to which the valid threshold voltage is set is a voltage higher than all threshold voltages Vth (q1), Vth (q2), and Vth (q3), and the second voltage Vread is a voltage higher than the first voltage Vcgr.

A current indicated by the plot p1, p2, or p3 in FIG. 12 flows between a drain and source of the transistor to which the valid threshold voltage is set. As illustrated in FIG. 12, because different currents flow for the respective threshold voltages, the query can be identified with a current value.

FIG. 13 is a table illustrating voltages supplied to gates of the respective transistors of the resistance adjustment layer 16 and key layer 15. FIG. 13 illustrates an example in which the query and the key take on four values.

In a case where the query is Q0, the SGD transistor is turned off. Therefore, voltages supplied to the gates of the respective transistors of the resistance adjustment layer 16 are irrelevant. In a case where the query is Q1, a threshold value corresponding to Q1 is set to a transistor of the resistance adjustment layer 16, the transistor corresponding to Q1. The first voltage Vcgr is supplied to the gate of the transistor, and the second voltage Vread is supplied to the gates of the other transistors. In a case where the query is Q2, a threshold value corresponding to Q2 is set to a transistor of the resistance adjustment layer 16, the transistor corresponding to Q2. The first voltage Vcgr is supplied to the gate of the transistor, and the second voltage Vread is supplied to the gates of the other transistors. In a case where the query is Q3, a threshold value corresponding to Q3 is set to a transistor of the resistance adjustment layer 16, the transistor corresponding to Q3. The first voltage Vcgr is supplied to the gate of the transistor, and the second voltage Vread is supplied to the gates of the other transistors.

A threshold value corresponding to the key is set to a transistor of the selected key layer 15a of the key layer 15 regardless of the query value, and the first voltage Vcgr is supplied to the gate of the transistor. A predetermined threshold value is set to a transistor of the non-selected key layer 15b of the key layer 15 regardless of the query value, and the second voltage Vread is supplied to the gate of the transistor.

As described above, in the information processing apparatus 10 according to the first embodiment, the plurality of strings 11 including the first string 11a and second string 11b connected to the same bit line BL (first wiring line) is provided, and each string 11 includes the key layer 15 and the resistance adjustment layer 16. A threshold value corresponding to the key is set to each transistor of the selected key layer 15a of the key layer 15, and the first voltage Vcgr is supplied to the gate of the transistor. A threshold value corresponding to all types of queries is set to each transistor included in the resistance adjustment layer 16. The first voltage Vcgr is supplied to the gate of a transistor to which the threshold value corresponding to the query value is set, and the second voltage Vread is supplied to the gates of the other transistors. As a result, it is possible to perform the inner product operation of the query and the key without providing a query selector 17b1 in FIG. 7 that selects the voltage of the query, and it is possible to reduce a circuit scale.

According to a circuit configuration of the information processing apparatus 10 according to the first embodiment illustrated in FIG. 9, the number of stages of the transistors of the resistance adjustment layer 16 is increased as compared with a circuit configuration of the information processing apparatus 100 according to a comparative example illustrated in FIG. 7. However, in a case where the information processing apparatus 10 according to the first embodiment is implemented by a non-volatile memory such as a NAND flash memory, for example, the number of stages of the memory cell transistors of each string 11 will further increase in the future along with an increase in the number of stacked layers. Therefore, even if the number of stages of the transistors of the resistance adjustment layer 16 increases, a sufficient number of stages of transistors can be secured for the key layer 15, and thus there is no problem in the inner product operation of the query and the key.

### Second Embodiment

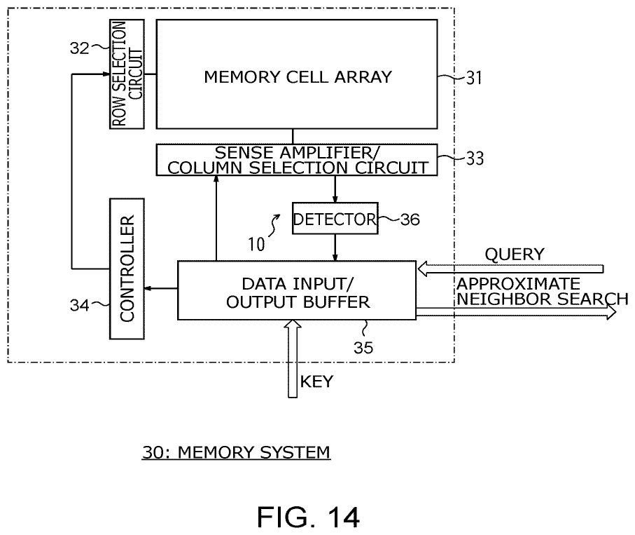

FIG. 14 is a block diagram illustrating a schematic configuration of a memory system 30 including an information processing apparatus 10 according to a second embodiment. The memory system 30 in FIG. 14 includes a memory cell array 31, a row selection circuit 32, a sense amplifier/column selection circuit 33, a controller 34, a data input/output buffer 35, and a detector 36. At least the memory cell array 31, the sense amplifier/column selection circuit 33, and the detector 36 in FIG. 14 constitute the information processing apparatus 10.

Similarly to FIG. 9, the memory cell array 31 includes a plurality of strings 11 including a first string 11a and second string 11b connected to the same bit line BL. Similarly to FIG. 9, a plurality of bit lines BL may be arranged in the memory cell array 31.

Each string 11 in the memory cell array 31 is read or written, for example, in units of blocks. As described above, the plurality of strings 11 arranged in a direction in which the word lines (second wiring line to fifth wiring line) in FIG. 9 extend is included in the same block. Each block is provided with a plurality of strings 11 connected to different bit lines BL.

The row selection circuit 32 drives word lines (second wiring line to fifth wiring line) WL in accordance with an instruction from the controller 34. In order to set a threshold voltage for each transistor of a key layer 15 and resistance adjustment layer 16 of each string 11, the row selection circuit 32 drives the word lines (second wiring line to fifth wiring line) WL connected to gates of the transistors.

The row selection circuit 32 sets a threshold voltage for each transistor of the key layer 15 and the resistance adjustment layer 16, and then supplies a first voltage Vcgr or a second voltage Vread to each word line (second wiring line to fifth wiring line). As a result, in each string 11, an inner product operation of the query and the key is performed, and a current corresponding to an inner product value flows through each string 11.

The data input/output buffer 35 acquires a key K from outside, and supplies the acquired key K to the sense amplifier/column selection circuit 33 according to an instruction from the controller 34. The sense amplifier/column selection circuit 33 supplies the key K output from the data input/output buffer 35 to the bit line BL.

The detector 36 performs an approximate neighbor search of the key and query based on at least one of the current flowing through the bit line BL or a voltage of the bit line BL, and outputs the result. The result of the approximate neighbor search that is output by the detector 36 is output via the data input/output buffer 6.

The information processing apparatus 10 in FIG. 14 may be capable of alternatively selecting a mode in which the memory cell array 31 is used as a normal memory and a mode in which a multiply-accumulate operation of the first data K and the second data Q is performed.

In addition, the memory cell array 31 may include a memory cell area used as a normal memory and a memory cell area for performing a multiply-accumulate operation of the first data K and the second data Q.

As described above, in the second embodiment, a processing operation similar to a processing operation by the information processing apparatus 10 according to the first embodiment is performed by using a semiconductor memory having a configuration substantially equivalent to that of a configuration of a normal memory. Because the information processing apparatus 10 that performs the multiply-accumulate operation can be constructed only by partially changing an internal configuration of a normal memory, design is easy, and the information processing apparatus 10 can be manufactured by using a short design time and an existing semiconductor process.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. An information processing apparatus comprising:
a first string including a first portion and a second portion connected in series;
a second string including a third portion and a fourth portion connected in series;
a first wiring line to which one end of the first string and one end of the second string are connected;
a first switching controller that switches and controls currents flowing through the first portion and the third portion;
a second switching controller that switches and controls a resistance value of the second portion; and
a third switching controller that switches and controls a resistance value of the fourth portion.

2. The information processing apparatus according to claim 1, wherein
the first string carries a first current corresponding to a product of first data set or input to the first portion and second data set or input to the second portion,
the second string carries a second current corresponding to a product of third data set or input to the third portion and fourth data set or input to the fourth portion, and
the first wiring line carries a third current obtained by adding the first current and the second current.

3. The information processing apparatus according to claim 2, wherein
the first currents corresponding to products of all combinations of types of the first data and types of the second data have different current values, and
the second currents corresponding to products of all combinations of types of the third data and types of the fourth data have different current values.

4. The information processing apparatus according to claim 2, wherein
the first switching controller switches and controls current flowing through the first portion and the third portion by supplying a common voltage to the first portion and the third portion,
the second switching controller switches and controls a resistance value of the second portion by supplying a voltage corresponding to the second data to the second portion, and
the third switching controller switches and controls a resistance value of the second portion by supplying a voltage corresponding to the fourth data to the fourth portion.

5. The information processing apparatus according to claim 4, wherein
the first portion includes a first transistor to which a threshold voltage corresponding to the first data is set,
the second portion includes a second transistor that is connected in series to the first transistor and to which a threshold voltage corresponding to the second data is set,
the third portion includes a third transistor for which a threshold voltage corresponding to the third data is set, and
the fourth portion includes a fourth transistor that is connected in series to the third transistor and to which a threshold voltage corresponding to the fourth data is set.

6. The information processing apparatus according to claim 5, wherein
the first switching controller supplies gates of the first transistor and the third transistor with a voltage having voltage level corresponding to a threshold voltage of the first transistor and a threshold voltage of the third transistor,
the second switching controller supplies a gate of the second transistor with a voltage having a voltage level corresponding to a threshold voltage of the second transistor, and
the third switching controller supplies a gate of the fourth transistor with a voltage having a voltage level corresponding to a threshold voltage of the fourth transistor.

7. The information processing apparatus according to claim 5, wherein
the second portion includes a first transistor group in which two or more second transistors of a number corresponding to types of the second data are connected in series,
the fourth portion includes a second transistor group in which two or more fourth transistors of a number corresponding to types of the fourth data are connected in series,
a threshold voltage corresponding to types of the second data is set to each of the two or more the second transistors included in the first transistor group, and
a threshold voltage corresponding to types of the fourth data is set to each of the two or more the fourth transistors included in the second transistor group.

8. The information processing apparatus according to claim 7, wherein
the second switching controller supplies a first voltage to a gate of a specific second transistor among the two or more second transistors included in the first transistor group, and supplies a second voltage having a voltage level higher than the first voltage to a gate of a second transistor other than the specific second transistor, and
the third switching controller supplies the first voltage to a gate of a specific fourth transistor among the two or more fourth transistors included in the second transistor group, and supplies the second voltage to a gate of a fourth transistor other than the specific fourth transistor.

9. The information processing apparatus according to claim 8, wherein
the specific second transistor in the first transistor group operates in a subthreshold region or a linear region, and a second transistor other than the specific second transistor operates in a saturation region or a linear region, and
the specific fourth transistor in the second transistor group operates in a subthreshold region or a linear region, and a fourth transistor other than the specific fourth transistor operates in a saturation region or a linear region.

10. The information processing apparatus according to claim 8, wherein
the first transistor group is configured by connecting a plurality of first sets to which different threshold voltages are set, each of the first sets including two or more the second transistors connected in series and having a seme threshold voltage;
the second transistor group is configured by connecting a plurality of second sets to which different threshold voltages are set, each of the second sets including two or more the fourth transistors connected in series and having a seme threshold voltage;
the second switching controller supplies the first voltage to gates of the second transistors of one of the first sets, and supplies the second voltage to gates of the second transistors of another of the first sets, and
the third switching controller supplies the first voltage to gates of the fourth transistors of one of the second sets, and supplies the second voltage to gates of the fourth transistors of another of the second set.

11. The information processing apparatus according to claim 8, wherein
the first switching controller supplies the first voltage and the second voltage to the first portion and the third portion.

12. The information processing apparatus according to claim 11, further comprising:
a second wiring line that is connected to the first switching controller and supplies the first voltage or the second voltage to a gate of the first transistor of the first portion and a gate of the third transistor of the third portion,
a third wiring line that is connected to the second switching controller and supplies the first voltage or the second voltage to a gate of the second transistor of the second portion, and
a fourth wiring line that is connected to the third switching controller and supplies the first voltage or the second voltage to a gate of the fourth transistor of the fourth portion.

13. The information processing apparatus according to claim 12, further comprising
a plurality of the first strings and a plurality of the second strings that are connected to the second wiring line, the third wiring line, and the fourth wiring line, and are respectively connected to different ones of the first wiring lines.

14. The information processing apparatus according to claim 11, wherein
the first portion includes a fifth transistor that is connected in series to the first transistor and has a gate to which the second voltage having a higher voltage level than the first voltage supplied to a gate of the first transistor is supplied, and
the third portion includes a sixth transistor that is connected in series to the third transistor and has a gate to which the second voltage having a higher voltage level than the first voltage supplied to a gate of the third transistor is supplied.

15. The information processing apparatus according to claim 14, wherein
the first transistor and the third transistor operate in a subthreshold region or a linear region, and
the fifth transistor and the sixth transistor operate in a saturation region or a linear region.

16. The information processing apparatus according to claim 14, further comprising
a fifth wiring line that is connected to the first switching controller, and to which a gate of the fifth transistor and a gate of the sixth transistor are connected.

17. The information processing apparatus according to claim 2, wherein
the first string includes a seventh transistor that switches whether or not to interrupt a current path of the first string, and
the second string includes an eighth transistor that switches whether or not to interrupt a current path of the second string.

18. The information processing apparatus according to claim 17, wherein
the seventh transistor is turned off when the second data has a predetermined value, and interrupts a current path of the first string, and
the eighth transistor is turned off when the fourth data has a predetermined value, and interrupts a current path of the first string.

19. The information processing apparatus according to claim 18, wherein
the predetermined value is a minimum value of values to be taken as the second data or the fourth data.

20. A memory system comprising:
a non-volatile memory; and
a controller that controls writing and reading of data to and from the non-volatile memory, and performs an approximate neighbor search of first data and second data, and an approximate neighbor search of third data and fourth data, wherein
the non-volatile memory includes
a first string including a first portion and a second portion connected in series,
a second string including a third portion and a fourth portion connected in series,
a first wiring line to which one end of the first string and one end of the second string are connected,
a first switching controller that switches and controls currents flowing through the first portion and the third portion,
a second switching controller that switches and controls a resistance value of the second portion, and
a third switching controller that switches and controls a resistance value of the fourth portion,
the first string carries a first current corresponding to a product of the first data set or input to the first portion and the second data set or input to the second portion,
the second string carries a second current corresponding to a product of the third data set or input to the third portion and the fourth data set or input to the fourth portion,
the first wiring line carries a third current obtained by adding the first current and the second current, and
the controller outputs, based on the third current, a result of an approximate neighbor search of the first data and the second data, and a result of an approximate neighbor search of the third data and the fourth data.
